(19) United States
(12) Patent Application Publication
(10) Pub. No.: US 2024/0313771 A1
(43) Pub. Date: Sep. 19, 2024

(54) TIME MULTIPLEXING OF BOOTSTRAP SAMPLE NETWORK

(71) Applicant: Meta Platforms Technologies, LLC, Menlo Park, CA (US)

(72) Inventors: Umanath Ramachandra Kamath, Palo Alto, CA (US); Daniel Villamizar, Woodinville, WA (US); Yair Shachna Shemesh, Haifa (IL); Robert Wiser, Palo Alto, CA (US); Ramakrishna Chilukuri, San Jose, CA (US)

(21) Appl. No.: 18/184,936

(22) Filed: Mar. 16, 2023

(51) Int. Cl. H03K 17/687

(52) U.S. Cl. CPC H03K 17/6872

(57) ABSTRACT

In one embodiment, an electrical circuit module may include a bootstrap capacitor connected to a bootstrap-capacitor charging switch. A first signal channel may include a first sampling switch and a first control switch that controls a first connection between the bootstrap capacitor and a first control input of the first sampling switch. A second signal channel may include a second sampling switch and a second control switch that controls a second connection between the bootstrap capacitor and a second control input of the second sampling switch. The bootstrap capacitor may be charged during a first operation phase during which the bootstrap-capacitor charging switch is turned on. The first control switch of the first signal channel may be turned on during a first sub-phase of a second operation phase, and the second control switch of the second signal channel is turned on during a second sub-phase of the second operation phase.

### TECHNICAL FIELD

This disclosure generally relates to artificial reality, such as virtual reality and augmented reality.

### BACKGROUND

Artificial reality is a form of reality that has been adjusted in some manner before presentation to a user, which may include, e.g., a virtual reality (VR), an augmented reality (AR), a mixed reality (MR), a hybrid reality, or some combination and/or derivatives thereof. Artificial reality content may include completely generated content or generated content combined with captured content (e.g., real-world photographs). The artificial reality content may include video, audio, haptic feedback, or some combination thereof, and any of which may be presented in a single channel or in multiple channels (such as stereo video that produces a three-dimensional effect to the viewer). Artificial reality may be associated with applications, products, accessories, services, or some combination thereof, that are, e.g., used to create content in an artificial reality and/or used in (e.g., perform activities in) an artificial reality. The artificial reality system that provides the artificial reality content may be implemented on various platforms, including a head-mounted display (HMD) connected to a host computer system, a standalone HMD, a mobile device or computing system, or any other hardware platform capable of providing artificial reality content to one or more viewers.

### SUMMARY OF PARTICULAR EMBODIMENTS

Particular embodiments described herein relate to a method of using a single capacitor to bootstrap multiple transistor-switches which controls input-output signal channels to reduce the number of capacitors and thus, reduce the space used by analog filtering and sampling circuits. Such transistor-switches for controlling the input-output signal channels to the sampling capacitors may be referred to as “sampling switch” to be differentiated from other transistor-switches in this disclosure. Different sampling switches may share the same bootstrap capacitor in a multiplexing manner. In other words, each sampling switch may use the bootstrap capacitor during a different time window, and all sampling switches may work sequentially in time in a multiplexing manner. In one example, an analog signal filtering circuit may include circuits for three filter channels A, B, and C. Each channel may include a sampling switch which is connected to a separate sampling capacitor at the output end, but all three channels may be connected to the same input signal. Each channel's output sampling capacitor may sample the input signal at a different time as controlled by control signals. The values held by the three output sampling capacitors may mathematically correspond to a time average of the input signal (and thus the circuit may function as a filter). The output sampling capacitors may perform delayed sampling based on time instants thus leading to implementation of filtering such as Finite Impulse Response (FIR) filtering.

The operation process of the analog signal filtering circuit may include two phases. In the first phase, the sampling switches for all three channels may be turned off. The switches for charging the bootstrap capacitor may be turned on and the bootstrap capacitor may be charged for a pre-determined time duration. In the second phase, the switches for charging the bootstrap capacitor may be turned off. The bootstrap capacitor, which has been charged, may be ready to bootstrap the sampling switches. The second phase may include three sub-phases each for one channel. In the first sub-phase for the channel A, the system may switch on the connection of the bootstrap capacitor to the channel A, whose sampling switch may be now bootstrapped. The sampling switch of channel A may be turned on to allow the input signal to pass through it and to be captured by the output sampling capacitor of the channel A. In the second sub-phase for the channel B, the system may switch off the connection of the bootstrap capacitor to the channel A and switch on the connection to channel B, whose sampling switch may be now bootstrapped and turned on. The input signal may pass through the sampling switch of channel B and may be captured by the output sampling capacitor of channel B. In the third sub-phase for the channel C. the system may switch off the connection of the bootstrap capacitor to the channel B and switch on the connection to channel C. Now, the channel C′s sampling switch may be bootstrapped and turned on, to allow the input signal to pass through it and to be captured by the output sampling capacitor of the channel C. In short, in the first phase for charging the bootstrap capacitor, all three sampling switches may be turned off and all switches connecting the bootstrap capacitor to the three sampling switches may be turned off. In the second phase, at any time, only one switch for connecting the bootstrap capacitor to one sampling switch may be turned on, and only that sampling switch may be turned on. After all the sub-phases are completed, the system clock may start a new cycle, which includes its own first phase (to charge the bootstrap capacitor) and second phase of operation (to bootstrap each channel and sample the input signal by each channel). It is notable that the three-channel circuit is only for example purpose, and the electric circuit is not limited thereto. For example, the electrical circuit may include two or more channels each with a sampling switch.

The switches for charging the bootstrap capacitor may include three PMOS type transistors, which are controlled by the three channel's on/off status, respectively. Only when all three channels are turned off, the three PMOS type transistors may be turned on to allow the bootstrap capacitor to be charged. Each sampling switch may include two NMOS transistors (connected in a reverse series order). In another example for signal sampling application, each channel may be connected to a separate input signal (rather than being connected to the same input signal as in the first example for signal filtering application). Such circuit may function as an analog sampling circuit, allowing the input signals (which can be from different sensors) to be temporally held by the output sampling capacitors of respective channels to be later processed sequentially by a single A/D converter.

The embodiments disclosed herein are only examples, and the scope of this disclosure is not limited to them. Particular embodiments may include all, some, or none of the components, elements, features, functions, operations, or steps of the embodiments disclosed above. Embodiments according to the invention are in particular disclosed in the attached claims directed to a method, a storage medium, a system and a computer program product, wherein any feature mentioned in one claim category, e.g., method, can be claimed in another claim category, e.g. system, as well. The dependencies or references back in the attached claims are chosen for formal reasons only. However, any subject matter resulting from a deliberate reference back to any previous claims (in particular multiple dependencies) can be claimed as well, so that any combination of claims and the features thereof are disclosed and can be claimed regardless of the dependencies chosen in the attached claims. The subject-matter which can be claimed comprises not only the combinations of features as set out in the attached claims but also any other combination of features in the claims, wherein each feature mentioned in the claims can be combined with any other feature or combination of other features in the claims. Furthermore, any of the embodiments and features described or depicted herein can be claimed in a separate claim and/or in any combination with any embodiment or feature described or depicted herein or with any of the features of the attached claims.

### BRIEF DESCRIPTION OF THE DRAWINGS

FIG. 1A illustrates an example artificial reality system.

FIG. 1B illustrates an example augmented reality system.

FIG. 1C illustrates an example architecture of a display engine.

FIG. 1D illustrates an example graphic pipeline of the display engine for generating

display image data.

FIG. 2 illustrates an example bootstrap switch module with a bootstrap capacitor.

FIG. 3A illustrates an example FIR/IIR circuit with multiple switch modules for sampling the input signal.

FIG. 3B illustrates an example operation process showing the operation process of multiple switch modules sharing the same bootstrap capacitor.

FIG. 4 illustrates an example electrical circuit having multiple sampling switches sharing a single bootstrapping capacitor in a time multiplexing manner.

FIG. 5 illustrates an example scheme for the control signals used to control the two-phase operation process.

FIG. 6 illustrates an example electrical circuit having a separate input signal for each channel and multiple sampling switches sharing a single bootstrapping capacitor in a time multiplexing manner.

FIGS. 7A-7C illustrate example implementations of the sampling switches with multiple transistor switches arranged in series.

FIG. 8 illustrates an example method of bootstrapping multiple switches using a single bootstrapping capacitor.

### DESCRIPTION OF EXAMPLE EMBODIMENTS

The number of available bits in a display may limit the display's color depth or gray scale levels. To achieve display results with higher effective grayscale level, displays may use a series of temporal subframes with less grayscale level bits to create the illusion of a target image with more grayscale level bits. The series of subframes may be generated using a segmented quantization process with each segment having a different weight. The quantization errors may be dithered spatially within each subframe. However, the subframes generated in this way may have a naïve stacking property (e.g., direct stacking property without using a dither mask) and each subframe may be generated without considering what has been displayed in former subframes causing the subframes to have some artifacts that could negatively impact the experience of the viewers.

In particular embodiments, the system may use a mask-based spatio-temporal dithering method for generating each subframe of a series of subframes taking into consideration what has been displayed in the previous subframes preceding that subframe. The system may determine target pixel values of current subframe by compensating the quantization errors of the previously subframes. The pixel values of the current subframe may be determined by quantizing the target pixel values based on a dither mask having a spatial stacking property. The quantization errors may be propagated into subsequent subframes through an error buffer. The generated subframes may satisfy both spatial and temporal stacking property and provide better image display results and better user experience.

Particular embodiments of the system may provide better image quality and improve user experience for AR/VR display by using multiple subframe images with less color depth to represent an image with greater color depth. Particular embodiments of the system may generate subframe images with reduced or eliminated temporal artifacts. Particular embodiments of the system may allow AR/VR display system to reduce the space and complexity of pixel circuits by having less gray level bits, and therefore miniaturize the size of the display system. Particular embodiments of the system may make it possible for AR/VR displays to operate in monochrome mode with digital pixel circuits without using analog pixel circuits for full RGB operations.

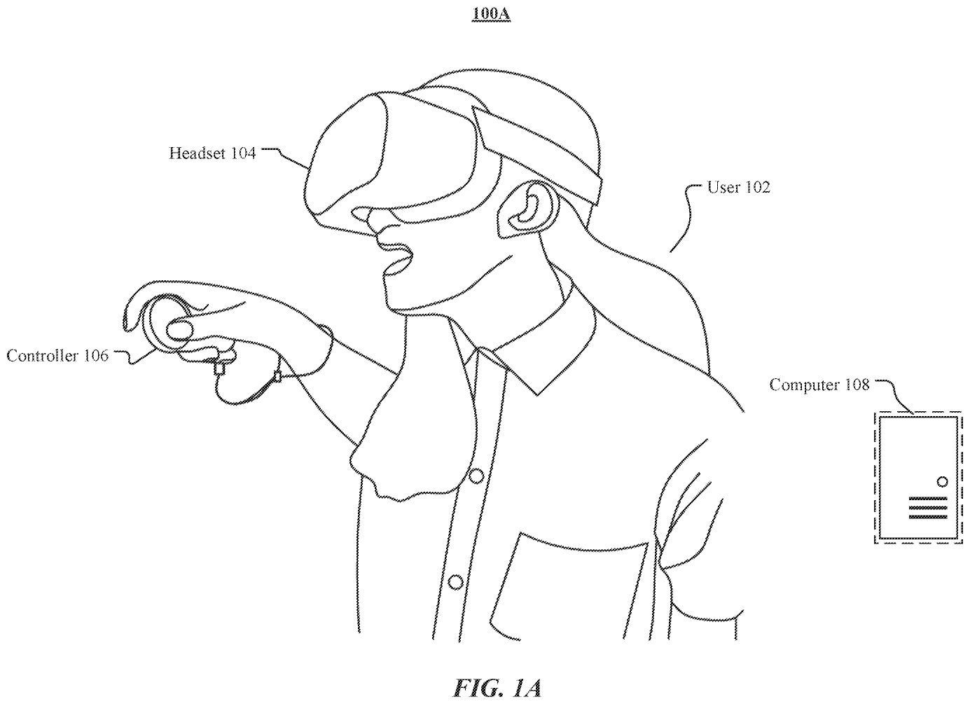

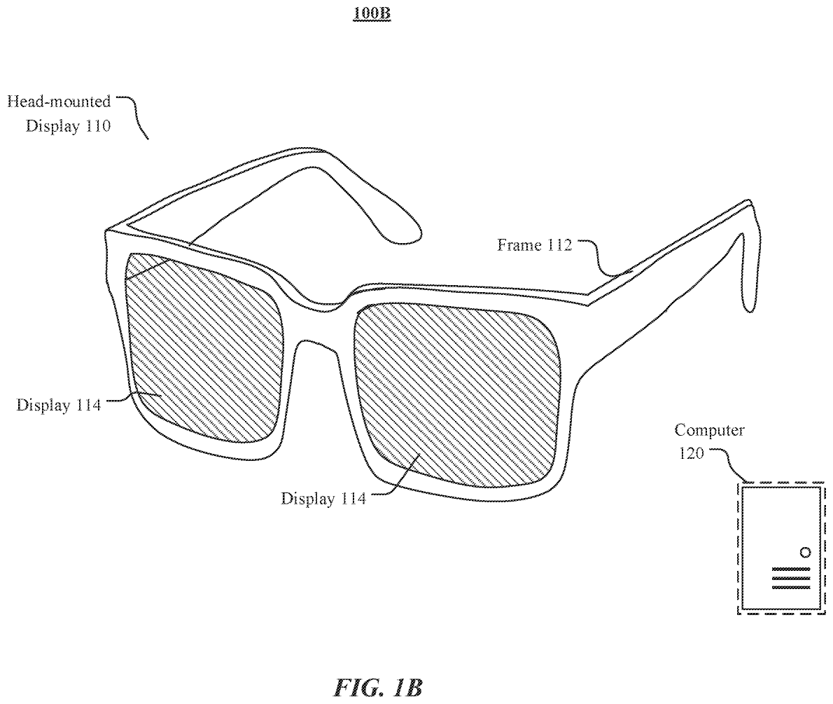

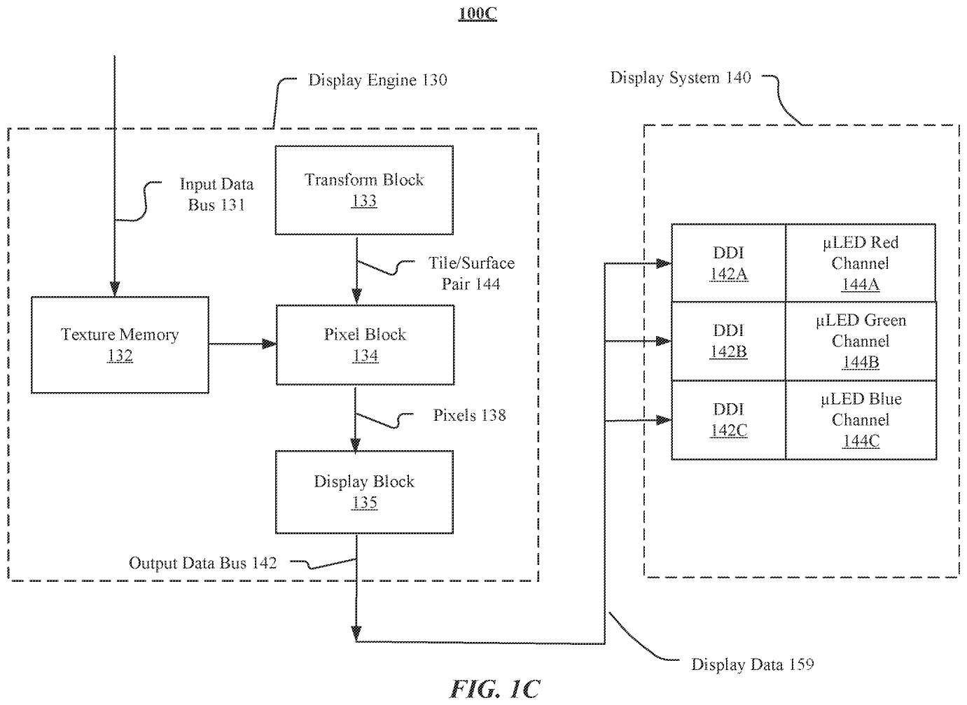

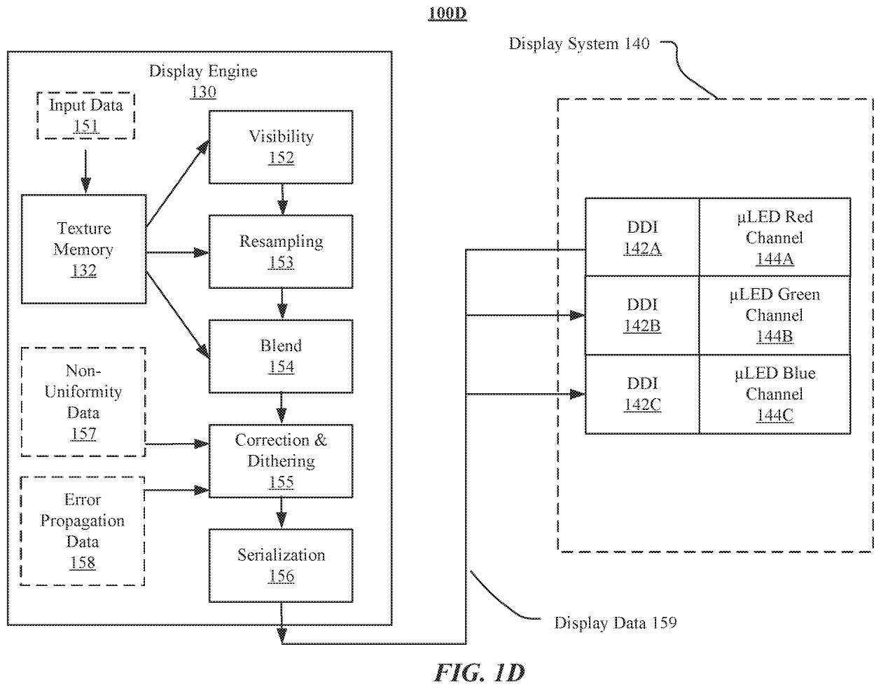

FIG. 1A illustrates an example artificial reality system 100A. In particular embodiments, the artificial reality system 100 may comprise a headset 104, a controller 106, and a computing system 108. A user 102 may wear the headset 104 that may display visual artificial reality content to the user 102. The headset 104 may include an audio device that may provide audio artificial reality content to the user 102. The headset 104 may include one or more cameras which can capture images and videos of environments. The headset 104 may include an eye tracking system to determine the vergence distance of the user 102. The headset 104 may be referred as a head-mounted display (HDM). The controller 106 may comprise a trackpad and one or more buttons. The controller 106 may receive inputs from the user 102 and relay the inputs to the computing system 108. The controller 206 may also provide haptic feedback to the user 102. The computing system 108 may be connected to the headset 104 and the controller 106 through cables or wireless connections. The computing system 108 may control the headset 104 and the controller 106 to provide the artificial reality content to and receive inputs from the user 102. The computing system 108 may be a standalone host computer system, an on-board computer system integrated with the headset 104, a mobile device, or any other hardware platform capable of providing artificial reality content to and receiving inputs from the user 102.

FIG. 1B illustrates an example augmented reality system 100B. The augmented reality system 100B may include a head-mounted display (HMD) 110 (e.g., glasses) comprising a frame 112, one or more displays 114, and a computing system 120. The displays 114 may be transparent or translucent allowing a user wearing the HMD 110 to look through the displays 114 to see the real world and displaying visual artificial reality content to the user at the same time. The HMD 110 may include an audio device that may provide audio artificial reality content to users. The HMD 110 may include one or more cameras which can capture images and videos of environments. The HMD 110 may include an eye tracking system to track the vergence movement of the user wearing the HMD 110. The augmented reality system 100B may further include a controller comprising a trackpad and one or more buttons. The controller may receive inputs from users and relay the inputs to the computing system 120. The controller may also provide haptic feedback to users. The computing system 120 may be connected to the HMD 110 and the controller through cables or wireless connections. The computing system 120 may control the HMD 110 and the controller to provide the augmented reality content to and receive inputs from users. The computing system 120 may be a standalone host computer system, an on-board computer system integrated with the HMD 110, a mobile device, or any other hardware platform capable of providing artificial reality content to and receiving inputs from users.

FIG. 1C illustrates an example architecture 100C of a display engine 130. In particular embodiments, the processes and methods as described in this disclosure may be embodied or implemented within a display engine 130 (e.g., in the display block 135). The display engine 130 may include, for example, but is not limited to, a texture memory 132, a transform block 133, a pixel block 134, a display block 135, input data bus 131, output data bus 142, etc. In particular embodiments, the display engine 130 may include one or more graphic pipelines for generating images to be rendered on the display. For example, the display engine may use the graphic pipeline(s) to generate a series of subframe images based on a mainframe image and a viewpoint or view angle of the user as measured by one or more eye tracking sensors. The mainframe image may be generated or/and loaded in to the system at a mainframe rate of 30-90 Hz and the subframe rate may be generated at a subframe rate of 1-2 kHz. In particular embodiments, the display engine 130 may include two graphic pipelines for the user's left and right eyes. One of the graphic pipelines may include or may be implemented on the texture memory 132, the transform block 133, the pixel block 134, the display block 135, etc. The display engine 130 may include another set of transform block, pixel block, and display block for the other graphic pipeline. The graphic pipeline(s) may be controlled by a controller or control block (not shown) of the display engine 130. In particular embodiments, the texture memory 132 may be included within the control block or may be a memory unit external to the control block but local to the display engine 130. One or more of the components of the display engine 130 may be configured to communicate via a high-speed bus, shared memory, or any other suitable methods. This communication may include transmission of data as well as control signals, interrupts or/and other instructions. For example, the texture memory 132 may be configured to receive image data through the input data bus 211. As another example, the display block 135 may send the pixel values to the display system 140 through the output data bus 142. In particular embodiments, the display system 140 may include three color channels (e.g., 114A, 114B, 114C) with respective display driver ICs (DDIs) of 142A, 142B, and 143B. In particular embodiments, the display system 140 may include, for example, but is not limited to, light-emitting diode (LED) displays, organic light-emitting diode (OLED) displays, active matrix organic light-emitting diode (AMLED) displays, liquid crystal display (LCD), micro light-emitting diode (uLED) display, electroluminescent displays (ELDs), or any suitable displays.

In particular embodiments, the display engine 130 may include a controller block (not shown). The control block may receive data and control packages such as position data and surface information from controllers external to the display engine 130 though one or more data buses. For example, the control block may receive input stream data from a body wearable computing system. The input data stream may include a series of mainframe images generated at a mainframe rate of 30-90 Hz. The input stream data including the mainframe images may be converted to the required format and stored into the texture memory 132. In particular embodiments, the control block may receive input from the body wearable computing system and initialize the graphic pipelines in the display engine to prepare and finalize the image data for rendering on the display. The data and control packets may include information related to, for example, one or more surfaces including texel data, position data, and additional rendering instructions. The control block may distribute data as needed to one or more other blocks of the display engine 130. The control block may initiate the graphic pipelines for processing one or more frames to be displayed. In particular embodiments, the graphic pipelines for the two eye display systems may each include a control block or share the same control block.

In particular embodiments, the transform block 133 may determine initial visibility information for surfaces to be displayed in the artificial reality scene. In general, the transform block 133 may cast rays from pixel locations on the screen and produce filter commands (e.g., filtering based on bilinear or other types of interpolation techniques) to send to the pixel block 134. The transform block 133 may perform ray casting from the current viewpoint of the user (e.g., determined using the headset's inertial measurement units, eye tracking sensors, and/or any suitable tracking/localization algorithms, such as simultaneous localization and mapping (SLAM)) into the artificial scene where surfaces are positioned and may produce tile/surface pairs 144 to send to the pixel block 134. In particular embodiments, the transform block 133 may include a four-stage pipeline as follows. A ray caster may issue ray bundles corresponding to arrays of one or more aligned pixels, referred to as tiles (e.g., each tile may include 16×16 aligned pixels). The ray bundles may be warped, before entering the artificial reality scene, according to one or more distortion meshes. The distortion meshes may be configured to correct geometric distortion effects stemming from, at least, the eye display systems the headset system. The transform block 133 may determine whether each ray bundle intersects with surfaces in the scene by comparing a bounding box of each tile to bounding boxes for the surfaces. If a ray bundle does not intersect an object, it may be discarded. After the tile-surface intersections are detected, the corresponding tile/surface pairs may be passed to the pixel block 134.

In particular embodiments, the pixel block 134 may determine color values or grayscale values for the pixels based on the tile-surface pairs. The color values for each pixel may be sampled from the texel data of surfaces received and stored in texture memory 132. The pixel block 134 may receive tile-surface pairs from the transform block 133 and may schedule bilinear filtering using one or more filer blocks. For each tile-surface pair, the pixel block 134 may sample color information for the pixels within the tile using color values corresponding to where the projected tile intersects the surface. The pixel block 134 may determine pixel values based on the retrieved texels (e.g., using bilinear interpolation). In particular embodiments, the pixel block 134 may process the red, green, and blue color components separately for each pixel. In particular embodiments, the display may include two pixel blocks for the two eye display systems. The two pixel blocks of the two eye display systems may work independently and in parallel with each other. The pixel block 134 may then output its color determinations (e.g., pixels 138) to the display block 135. In particular embodiments, the pixel block 134 may composite two or more surfaces into one surface to when the two or more surfaces have overlapping areas. A composed surface may need less computational resources (e.g., computational units, memory, power, etc.) for the resampling process.

In particular embodiments, the display block 135 may receive pixel color values from the pixel block 134, covert the format of the data to be more suitable for the scanline output of the display, apply one or more lightness corrections to the pixel color values, and prepare the pixel color values for output to the display. In particular embodiments, the display block 135 may cach include a row buffer and may process and store the pixel data received from the pixel block 134. The pixel data may be organized in quads (e.g., 2×2 pixels per quad) and tiles (e.g., 16×16 pixels per tile). The display block 135 may convert tile-order pixel color values generated by the pixel block 134 into scanline or row-order data, which may be required by the physical displays. The lightness corrections may include any required lightness correction, gamma mapping, and dithering. The display block 135 may output the corrected pixel color values directly to the driver of the physical display (e.g., pupil display) or may output the pixel values to a block external to the display engine 130 in a variety of formats. For example, the eye display systems of the headset system may include additional hardware or software to further customize backend color processing, to support a wider interface to the display, or to optimize display speed or fidelity.

In particular embodiments, the dithering methods and processes (e.g., spatial dithering method, temporal dithering methods, and spatio-temporal methods) as described in this disclosure may be embodied or implemented in the display block 135 of the display engine 130. In particular embodiments, the display block 135 may include a model-based dithering algorithm or a dithering model for each color channel and send the dithered results of the respective color channels to the respective display driver ICs (e.g., 142A, 142B, 142C) of display system 140. In particular embodiments, before sending the pixel values to the respective display driver ICs (e.g., 142A, 142B, 142C), the display block 135 may further include one or more algorithms for correcting, for example, pixel non-uniformity, LED non-ideality, waveguide non-uniformity, display defects (e.g., dead pixels), etc.

In particular embodiments, graphics applications (e.g., games, maps, content-providing apps, etc.) may build a scene graph, which is used together with a given view position and point in time to generate primitives to render on a GPU or display engine. The scene graph may define the logical and/or spatial relationship between objects in the scene. In particular embodiments, the display engine 130 may also generate and store a scene graph that is a simplified form of the full application scene graph. The simplified scene graph may be used to specify the logical and/or spatial relationships between surfaces (e.g., the primitives rendered by the display engine 130, such as quadrilaterals or contours, defined in 3D space, that have corresponding textures generated based on the mainframe rendered by the application). Storing a scene graph allows the display engine 130 to render the scene to multiple display frames and to adjust cach element in the scene graph for the current viewpoint (e.g., head position), the current object positions (e.g., they could be moving relative to each other) and other factors that change per display frame. In addition, based on the scene graph, the display engine 130 may also adjust for the geometric and color distortion introduced by the display subsystem and then composite the objects together to generate a frame. Storing a scene graph allows the display engine 130 to approximate the result of doing a full render at the desired high frame rate, while actually running the GPU or display engine 130 at a significantly lower rate.

FIG. 1D illustrates an example graphic pipeline 100D of the display engine 130 for generating display image data. In particular embodiments, the graphic pipeline 100D may include a visibility step 152, where the display engine 130 may determine the visibility of one or more surfaces received from the body wearable computing system. The visibility step 152 may be performed by the transform block (e.g., 2133 in FIG. 1C) of the display engine 130. The display engine 130 may receive (e.g., by a control block or a controller) input data 151 from the body-wearable computing system. The input data 151 may include one or more surfaces, texel data, position data, RGB data, and rendering instructions from the body wearable computing system. The input data 151 may include mainframe images with 30-90 frames per second (FPS). The main frame image may have color depth of, for example, 24 bits per pixel. The display engine 130 may process and save the received input data 151 in the texel memory 132. The received data may be passed to the transform block 133 which may determine the visibility information for surfaces to be displayed. The transform block 133 may cast rays for pixel locations on the screen and produce filter commands (e.g., filtering based on bilinear or other types of interpolation techniques) to send to the pixel block 134. The transform block 133 may perform ray casting from the current viewpoint of the user (e.g., determined using the headset's inertial measurement units, eye trackers, and/or any suitable tracking/localization algorithms, such as simultaneous localization and mapping (SLAM)) into the artificial scene where surfaces are positioned and produce surface-tile pairs to send to the pixel block 134.

In particular embodiments, the graphic pipeline 100D may include a resampling step 153, where the display engine 130 may determine the color values from the tile-surfaces pairs to produce pixel color values. The resampling step 153 may be performed by the pixel block 134 in FIG. 1C) of the display engine 130. The pixel block 134 may receive tile-surface pairs from the transform block 133 and may schedule bilinear filtering. For each tile-surface pair, the pixel block 134 may sample color information for the pixels within the tile using color values corresponding to where the projected tile intersects the surface. The pixel block 134 may determine pixel values based on the retrieved texels (e.g., using bilinear interpolation) and output the determined pixel values to the respective display block 135.

In particular embodiments, the graphic pipeline 100D may include a bend step 154, a correction and dithering step 155, a serialization step 156, etc. In particular embodiments, the bend step, correction and dithering step, and serialization steps of 154, 155, and 156 may be performed by the display block (e.g., 135 in FIG. 1C) of the display engine 130. The correction and dithering step 155 may be based on the non-uniformity data 157 and error propagation data 158. The display engine 130 may blend the display content for display content rendering, apply one or more lightness corrections to the pixel color values, perform one or more dithering algorithms for dithering the quantization errors both spatially and temporally, serialize the pixel values for scanline output for the physical display, and generate the display data 159 suitable for the display system 140. The display engine 130 may send the display data 159 to the display system 140. In particular embodiments, the display system 140 may include three display driver ICs (e.g., 142A, 142B, 142C) for the pixels of the three color channels of RGB (e.g., 144A, 144B, 144C). AR/VR systems may use analog filtering and sampling circuits, which include transistor-switches, to process analog signals. However, to make such switches to have optimal resistance, such switches need to be bootstrapped to a higher operation voltage because AR/VR system circuits operate at a low voltage to save power. Traditionally, to bootstrap such switches, each switch would need a separate bootstrap capacitor. As a result, these switches collectively would need a large space for the capacitors, which requires a larger space and leads to a large AR/VR headset. Furthermore, sensor interface may need to sample an analog input signal for further processing (e.g., digitization). Lower supply voltage which is driven by both ultra-low power as well as scaled technology nodes may necessitate bootstrapping the sampling switch to have a low and constant resistance when turned on to achieve low level of sampling distortion. Analog signal processing such as finite impulse response (FIR) filtering or analog compute switched capacitor implementation may need transistor switch modules for sampling purpose. Multiplexing many sensor inputs into one single back-end Analog-to-Digital (A/D) converter may also need a large number of bootstrapped switches for each sensor chain.

Particular embodiments described herein relate to a method of using a single capacitor to bootstrap multiple transistor-switches which controls input-output signal channels to reduce the number of capacitors and thus, reduce the space used by analog filtering and sampling circuits. Such transistor-switches for controlling the input-output signal channels may be referred to as “sampling switch” to be differentiated from other transistor-switches in this disclosure. Different sampling switches may share the same bootstrap capacitor in a multiplexing manner. In other words, each sampling switch may use the bootstrap capacitor during a different time window, and all sampling switches may work sequentially in time in a multiplexing manner. In one example, an analog signal filtering circuit may include circuits for three filter channels A, B, and C. Each channel may include a sampling switch which is connected to a sperate sampling capacitor at the output end, but all three channels may be connected to the same input signal. Each channel's output sampling capacitor may sample the input signal at a different time as controlled by control signals. The values held by the three output sampling capacitors may mathematically correspond to a time average of the input signal (and thus the circuit may function as a filter). In particular embodiments, the values held by the three output sampling capacitors may mathematically correspond to a combination of time average of sampled values with delay and the circuit may serve as a FIR filter.

The operation process of the analog signal filtering circuit may include two phases. In the first phase, the sampling switches for all three channels may be turned off. The switches for charging the bootstrap capacitor may be turned on and the bootstrap capacitor may be charged for a pre-determined time duration. In the second phase, the switches for charging the bootstrap capacitor may be turned off. The bootstrap capacitor, which has been charged, may be ready to bootstrap the sampling switches. The second phase may include three sub-phases each for one channel. In the first sub-phase for the channel A, the system may switch on the connection of the bootstrap capacitor to the channel A, whose sampling switch may be now bootstrapped. The sampling switch of channel A may be turned on to allow the input signal to pass through it and to be captured by the output sampling capacitor of the channel A. In the second sub-phase for the channel B, the system may switch off the connection of the bootstrap capacitor to the channel A and switch on the connection to channel B, whose sampling switch may be now bootstrapped and turned on. The input signal may pass through the sampling switch of channel B and may be captured by the output sampling capacitor of channel B. In the third sub-phase for the channel C. the system may switch off the connection of the bootstrap capacitor to the channel B and switch on the connection to channel C. Now, the channel C′s sampling switch may be bootstrapped and turned on, to allow the input signal to pass through it and to be captured by the output sampling capacitor of the channel C. In short, in the first phase for charging the bootstrap capacitor, all three sampling switches may be turned off and all switches connecting the bootstrap capacitor to the three sampling switches may be turned off. In the second phase, at any time, only one switch for connecting the bootstrap capacitor to one sampling switch may be turned on, and only that sampling switch may be turned on. After all the sub-phases are completed, the system clock may start a new cycle, which includes its own first phase (to charge the bootstrap capacitor) and second phase of operation (to bootstrap cach channel and sample the input signal by each channel). It is notable that the three-channel circuit is only for example purpose, and the electric circuit is not limited thereto. For example, the electrical circuit may include two or more channels cach with a sampling switch.

The switches for charging the bootstrap capacitor may include three PMOS type transistors, which are controlled by the three channel's on/off status, respectively. Only when all three channels are turned off, the three PMOS type transistors may be turned on to allow the bootstrap capacitor to be charged. Each sampling switch may include two NMOS transistors (connected in a reverse series order). In another example for signal sampling application, cach channel may be connected to a separate input signal (rather than being connected to the same input signal as in the first example for signal filtering application). Such circuit may function as an analog sampling circuit, allowing the input signals (which can be from different sensors) to be temporally held by the output sampling capacitors of respective channels to be later processed sequentially by a single A/D converter.

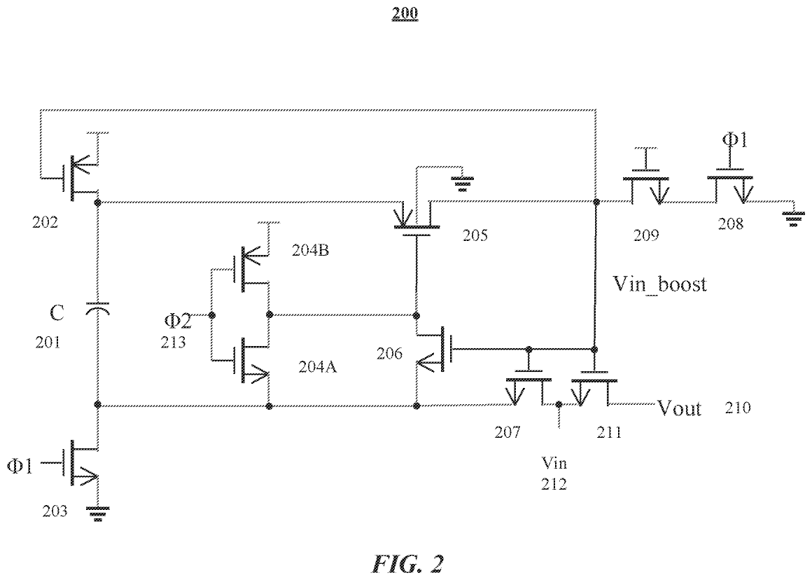

FIG. 2 illustrates an example bootstrap switch module 200 with a bootstrap capacitor 201. As an example and not by way of limitation, the bootstrap switch module 200 may include a bootstrap capacitor 201, which is controlled by the transistor switches 202 and 203. During a first operation phase, both the transistor 202 and 203 may be turned on and the bootstrap capacitor may be charged to a reference voltage during a pre-determined time period (e.g., the supply voltage Vdd). The transistor switch 203 may be controlled by the control signal Φ1. The transistor switch 202 may be controlled by the control signal (i.e., Vin_boost) on the control signal input of the transistor switch for sampling 211. Once the bootstrap capacitor 201 is charged, it may be ready to bootstrap the transistor switch for sampling 211. During a second operation phase, the transistor switch 205 may be turned on as controlled by the control signal Φ1 through the transistors 204A, 204B, and 206. When the transistor switch 205 is turned on, the bootstrap capacitor 201 may be connected to the control signal input end of the transistor switch for sampling 211, which is now bootstrapped by the voltage on the bootstrap capacitor 201. During the second operation phase when the transistor switch for sampling 211 is bootstrapped, the transistor switch for sampling 211 may be turned on. As a result, the input signal Vin may be added to stored voltage Vdd on the bootstrap capacitor thus forming Vin_boost (which equals to Vin+Vdd) of the transistor switch for sampling 211. The gate-to-source voltage of the sampling switch 211 may remain at Vg−Vs=(Vdd+Vin)−Vin, which is Vdd and may be independent of the input voltage Vin. Thus, the switch-on resistance may remain linear. The output voltage at the output of the sampling switch 211 may remain at Vin when switch is turned ON. In particular embodiments, the sampling switch may be implemented as a sub-module that includes two series transistor switches for reliability purpose, as described later in this disclosure.

In this disclosure, the transistor-switches for controlling the input-output signal channels between the signal input and the sampling capacitors may be referred to as “sampling switches” to be differentiated from other transistor-switches in this disclosure. The transistor switches that control the charging process of the bootstrap capacitor may be referred to as “bootstrap-capacitor charging switches,” or “switches for controlling the charging process the bootstrap capacitor.” The transistor switches that control the connection between the bootstrap capacitor and the control signal input of a sampling switch may be referred to as “control switches.” These switches may be transistor switches.

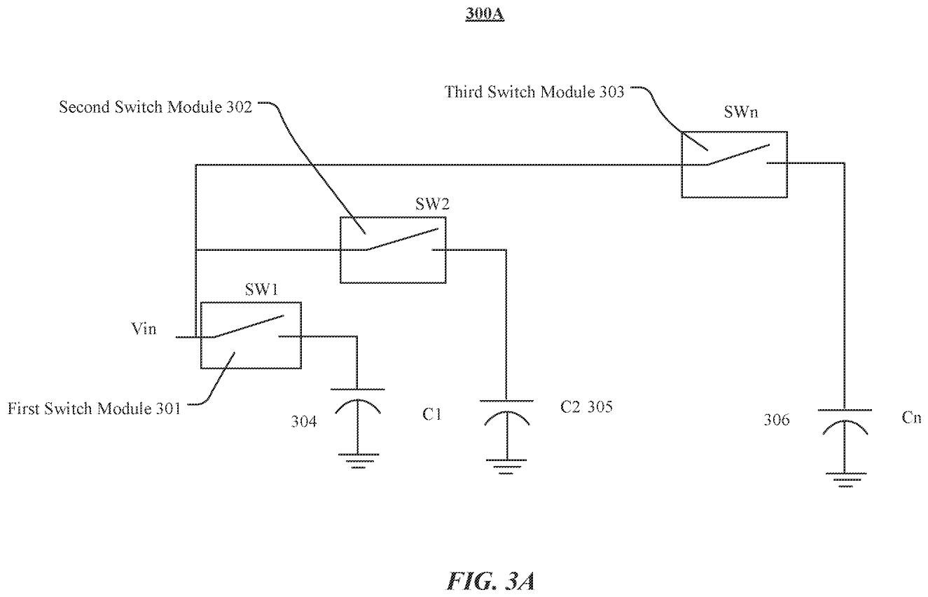

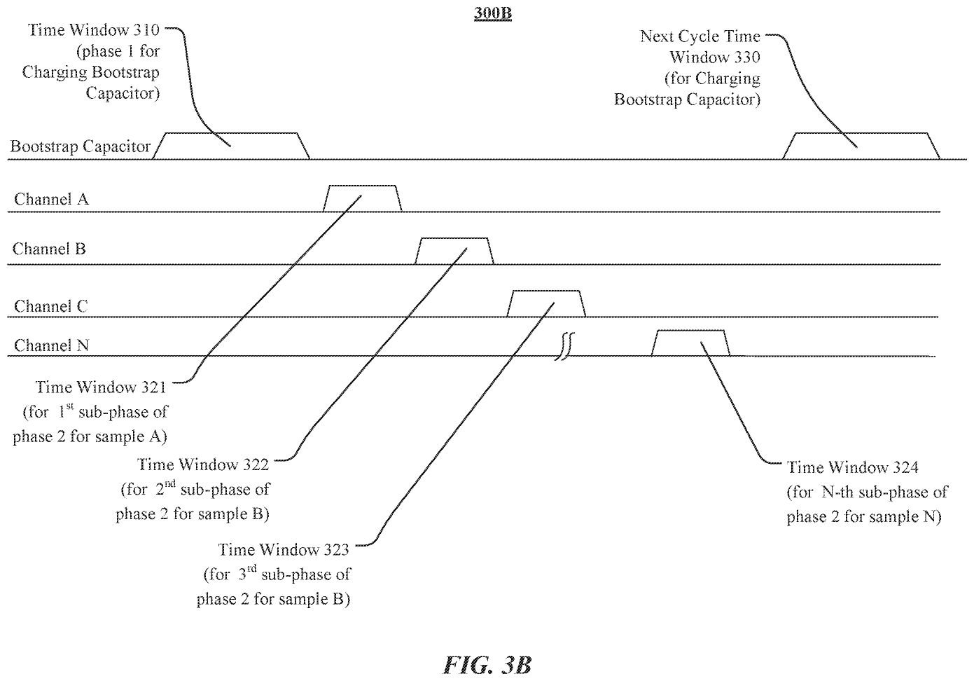

FIG. 3A illustrates an example FIR/IIR circuit with multiple switch modules (e.g., 301, 302, and 303) for sampling the input signal. In particular embodiments, the time multiplexing of bootstrap sample network may be applied in FIR/IIR filtering involves delayed sampling onto capacitors. In FIR/IIR filtering circuits, large number of caps(taps) may be used in order to have sharp roll-off. Other use cases may include anti-aliasing filter for ADC (analog-digital convertor). In order to relax the requirement of additional external RC filter size, large number of capacitors together with high sampling frequency may be used. In particular embodiments, a single bootstrap capacitor (rather than a large number of bootstrap capacitors) may be used to bootstrap the switches for sampling the input voltage to series of capacitors. The size of the bootstrap capacitor may be dependent on the tap capacitance value as well as precision/linearity required by the sampling switches. Each of the sampling switches may share the same bootstrap circuitry with the same bootstrap capacitor.

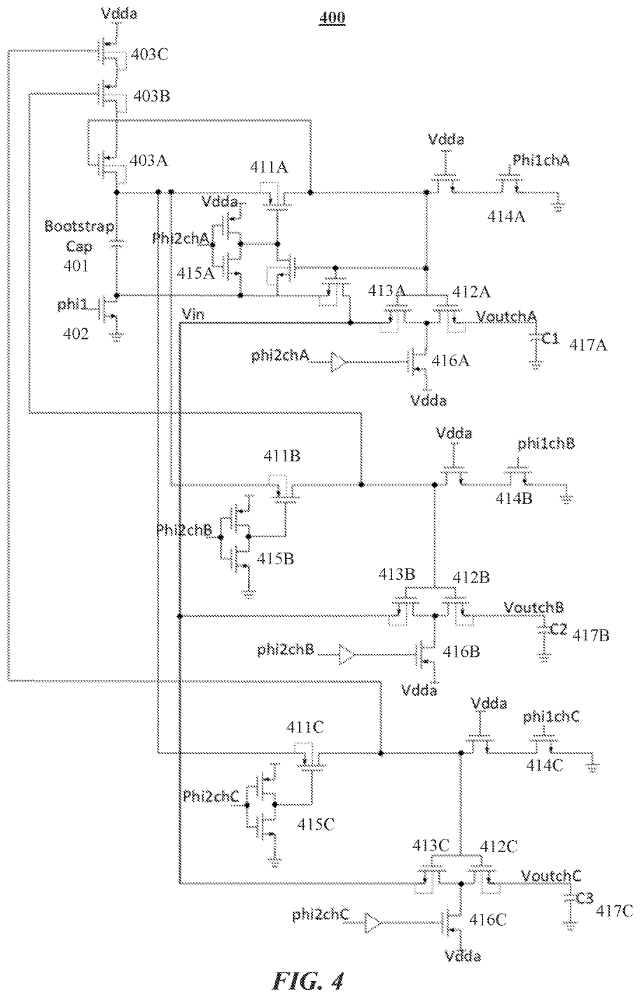

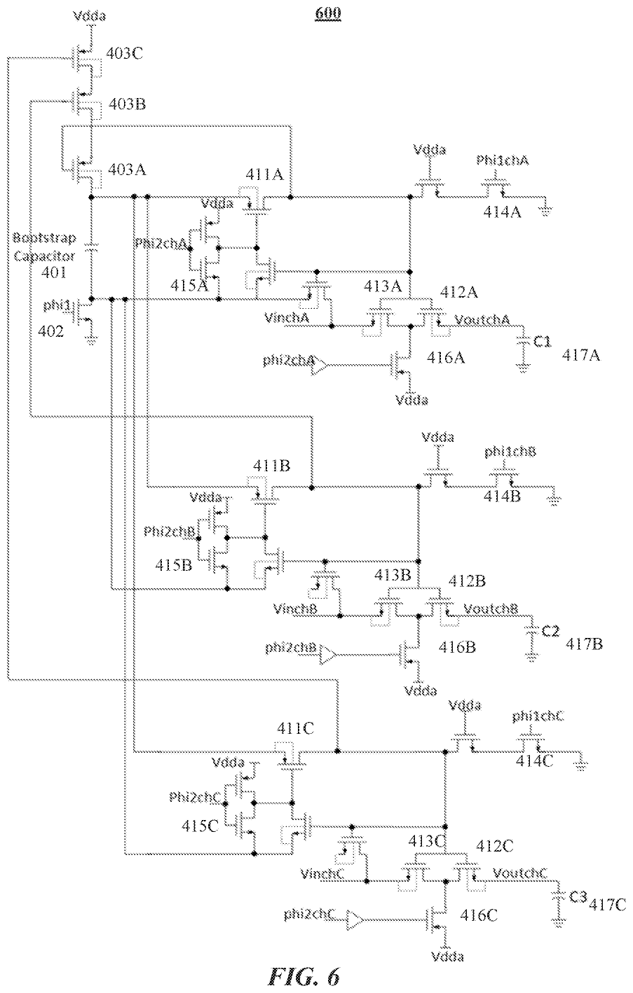

As an example and not by way of limitation, the FIR/IIR circuit may include N number of switch modules (e.g., 301, 302, and 303). All these switch modules (e.g., 301, 302, and 303) may be connected to the same input signal (Vin) but each switch module may be connected to a different sampling capacitor (e.g., 304, 305, and 306). Each switch module (e.g., 301, 302, and 303) may correspond to a bootstrap switch module, as shown in FIG. 2 or as shown in FIGS. 4 and 6. All switch modules (e.g., 301, 302, and 303) may share a same bootstrap capacitor circuit with a single bootstrap capacitor.

FIG. 3B illustrates an example operation process 300B showing the operation process of multiple switch modules sharing the same bootstrap capacitor. In particular embodiments, the multiple switch module may each include a sampling switch that need to be bootstrapped. The sampling switches of different switch modules may be bootstrapped by the same bootstrap circuit including the same bootstrap capacitor in a multiplexing manner. In other words, cach sampling switch may use the bootstrap capacitor during a different time window, and all sampling switches may work sequentially in time in a multiplexing manner. As an example and not by way of limitation, a signal filtering for filtering or sampling an input signal may include N number of signal channels (e.g., A. B. C, . . . N). Each signal channel may include a sampling switch which is connected to a sperate sampling capacitor at the output end, but all three channels may be connected to the same input signal. Each channel's output sampling capacitor may sample the input signal at a different time as controlled by corresponding control signals. The values held by the three output sampling capacitors may mathematically correspond to a time average of the input signal (and thus the electrical circuit may function as a filter).

The signal filtering circuit may use an operation process 300B including two phases. During the time window 310 of the first phase for charging the bootstrap capacitor, the sampling switches for all signal channels may be turned off. The switches for charging the bootstrap capacitor may be turned on and the bootstrap capacitor may be charged to a reference voltage (e.g., the supply voltage Vdd) for a pre-determined time duration. In particular embodiments, the reference voltage may be the supply voltage Vdd, a lower voltage than the supply voltage Vdd, or any suitable voltages. After being charged to the reference voltage level, the bootstrap capacitor may be ready to be used to bootstrap the sampling switches. The second phase of the operation process may include multiple sub-phases, each being associated with a time window dedicated for a particular signal channel. In the second phase, the switches for charging the bootstrap capacitor may be turned off. The time window 321 for the first sub-phase of the second phase may be assigned to the channel A. During the time window 321, the system may switch on the connection of the bootstrap capacitor to the channel A, whose sampling switch may be now bootstrapped. The sampling switch of channel A may be turned on to allow the input signal to pass through it and to be captured by the output sampling capacitor of the channel A.

Similarly, the time window 322 for the second sub-phase of the second phase may be assigned to the channel B. During the time window 322, the system may switch off the connection of the bootstrap capacitor to the channel A and switch on the connection to channel B, whose sampling switch may be now bootstrapped and turned on. The input signal may pass through the sampling switch of channel B and may be sampled by the output sampling capacitor of channel B. The time window 323 for the third sub-phase of the second phase may be assigned to the channel C. During the time window 323, the system may switch off the connection of the bootstrap capacitor to the channel B and switch on the connection to channel C. Now, the channel C′s sampling switch may be bootstrapped and turned on, to allow the input signal to pass through it and to be sampled by the output sampling capacitor of the channel C. The time window 324 for the N-th sub-phase of the second phase may be assigned to the channel N. During the time window 324, the system may switch off the connection of the bootstrap capacitor to all other channels and switch on the connection to channel N. Now, the channel N's sampling switch may be bootstrapped and turned on, to allow the input signal to pass through it and to be sampled by the output sampling capacitor of the channel N. After all signal channels have sampled the input signal, the operation process may start the next cycle which has its own two phases of operation (e.g., next cycle time window 330 for charging the bootstrap capacitor).

In summary, in the first phase for charging the bootstrap capacitor, all sampling switches for all signal channels may be turned off and all switches connecting the bootstrap capacitor to any sampling switches may be turned off. In the second phase, at any time, only one switch for connecting the bootstrap capacitor to one sampling switch may be turned on, and only that sampling switch may be turned on. After all the sub-phases are completed, the system clock may start a new cycle, which includes its own first phase (to charge the bootstrap capacitor) and second phase of operation (to bootstrap each channel and sample the input signal by each channel). It is notable that the electrical circuit may include any number of channels (e.g., two or more channels) with each channel having a sampling switch. In particular embodiments, the time duration for a sub-phase required by a sampling switch may be asynchronous or self-timed. For example, the time duration assigned for a sub-phase may be dynamically determined based on the speed requirements/setting for that channel and the different sub-phases for different channels may have different time durations based on respective speed requirements or/and settings.

FIG. 4 illustrates an example electrical circuit 400 having multiple sampling switches sharing a single bootstrapping capacitor in a time multiplexing manner. As an example and not by way of limitation, the electrical circuit 400 may be signal filtering circuit with three signal channels A, B, and C. The electrical circuit 400 may include a number of transistor switches for different functionality. To clearly describe the implementation, in this disclosure, the transistor-switches for controlling the input-output signal channels between the input signal and the sampling capacitors may be referred to as “sampling switches” to be differentiated from other transistor-switches in this disclosure. The transistor switches that control the charging process of the bootstrap capacitor may be referred to as “bootstrap-capacitor charging switches,” or “switches for charging the bootstrap capacitor.” The transistor switches that control the connection between the bootstrap capacitor and the control signal input of a sampling switch may be referred to as “control switches.” These switches may be transistor switches.

In this example, cach signal channel may include a sampling switch circuit which is connected to a sperate sampling capacitor at the output end, but all three channels may be connected to the same input signal. The sampling switch circuit for cach signal channel may include two series transistor switches for reliability purpose. For example, the sampling switch circuit for channel A may include the transistor switches of 412A and 413A, that is connected to the sampling capacitor 417A. The sampling switch circuit for channel B may include the transistor switches of 412B and 413B, that is connected to the sampling capacitor 417B. The sampling switch circuit for channel C may include the transistor switches of 412C and 413C, that is connected to the sampling capacitor 417C. Each channel's output sampling capacitor (e.g., 417A, 417B, 417C) may sample the input signal (Vin) at a different time as controlled by control signals. The values held by the three output sampling capacitors may mathematically correspond to a time average of the input signal (and thus the circuit may function as a filter). It is notable that these transistor pairs in series are for example purpose only and the sampling switches are not limited thereto. The sampling switch circuit may include any suitable number of transistor switches (i.e., one or more transistor switches).

In this example, the three channels A, B, and C may have their sampling switch circuits that share the same bootstrap capacitor 401 in a multiplexing manner. In other words, the sampling switch circuit of each channel may use the bootstrap capacitor during a different time window, and the sampling switch circuits for different channels may work sequentially in time in a multiplexing manner. The electrical circuit 400 may use an operation process having two phases. In the first phase, the sampling switches (e.g., 412A, 413A, 412B, 413B, 412C, 413B) for all three channels may be turned off. The bootstrap-capacitor charging switches 403A, 403B, and 403C may be turned on and the bootstrap capacitor 401 may be charged for a pre-determined time duration to a reference voltage level.

In the second phase, the bootstrap-capacitor charging switches 403A, 403B, and 403C may be turned off. The bootstrap capacitor 401, which has been charged, may be ready to bootstrap the sampling switches (e.g., 412A, 413A, 412B, 413B, 412C, 413B). The second phase may include three sub-phases each for one signal channel. In the first sub-phase for the channel A, the system may turn on the switch 411A to switch on the connection of the bootstrap capacitor 401 to the control signal input of the sampling switches 412A and 413A for the channel A. After the switch 411A is turned on, the sampling switches 412A and 413A may be bootstrapped to the reference voltage level on the bootstrap capacitor 401. The sampling switches 412A and 413A of channel A may be turned on to allow the input signal Vin to pass through them and to be sampled by the output sampling capacitor 417A of the channel A.

In the second sub-phase for the channel B, the system may turn off the switch 411A to switch off the connection of the bootstrap capacitor 401 to the control signal input of the sampling switches 412A and 413A of the channel A and turn on the switch 411B to switch on the connection to the control signal input of the sampling switches 412B and 413B of the channel B. After the switch 411B is turned on, the sampling switches 412B and 413B of the channel B may be bootstrapped and turned on. The input signal Vin may pass through the sampling switches 412B and 413B of channel B and may be sampled by the output sampling capacitor 417B of the channel B. In the third sub-phase for the channel C, the system may turn off the switches 411A and 411B to switch off the connection of the bootstrap capacitor to the channels B and C and turn on the switch 411C to switch on the connection to the control signal input of the sampling switches 412C and 413C of the channel C. After the switch 411C is turned on, the channel C's sampling switches 412C and 413C may be bootstrapped and turned on, to allow the input signal Vin to pass through them and to be sampled by the output sampling capacitor 417C of the channel C.

In short, in the first phase for charging the bootstrap capacitor 401, the sampling switches (412A, 413A, 412B, 413B, 412C, 413C) for all three channels A, B, and C may be turned off and all switches (411A, 411B, 411C) connecting the bootstrap capacitor to the control signal inputs of the three sampling switches may be turned off. During the first phase of the operation process, the bootstrap capacitor 401 may be charged to a reference voltage level during a pre-determined period of time. In the second phase, at any time, only one switch for connecting the bootstrap capacitor 401 to the sampling switches of one signal channel may be turned on, and only the sampling switches for that signal channel may be turned on. After all the sub-phases are completed, the system clock may start a new cycle, which includes its own first phase (to charge the bootstrap capacitor) and second phase of operation (to bootstrap each channel and sample the input signal by each channel). It is notable that the three-channel circuit is only for example purpose, and the electric circuit 400 is not limited thereto. For example, the electrical circuit 400 may include two or more channels each with a sampling switch circuit.

In particular embodiments, the switches for charging the bootstrap capacitor (e.g., 403A, 403B, 403C) may include three PMOS type transistors, which are controlled by the three channel's on/off status, respectively. Only when all three channels are turned off, the three PMOS type transistors (e.g., 403A, 403B, 403C) and the charging control switch 402 may be turned on to allow the bootstrap capacitor 401 to be charged. Each sampling switch circuit may include two NMOS transistors (connected in a reverse series order, as shown in FIG. 4).

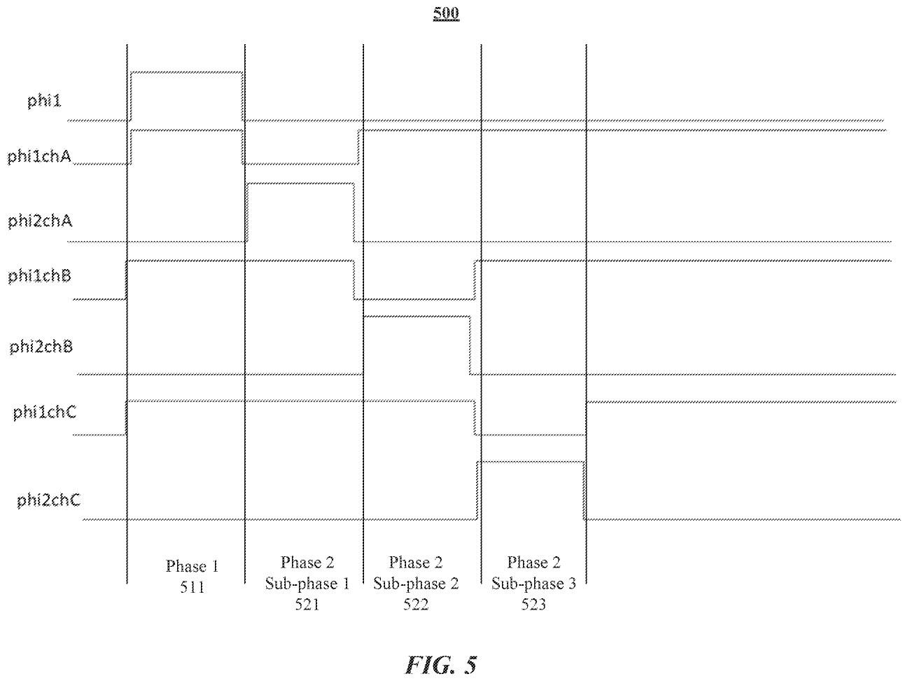

FIG. 5 illustrates an example scheme 500 for the control signals used to control the two-phase operation process. In particular embodiments, the two-phase operation process of the electrical circuit 400 may be controlled by a number of control signals including, for example, but not limited to, phi1, phi1chA, phi2chA, phi1chB, phi2chB, phi1chC, phi2chaC, etc. These control signals may be fed to corresponding control signal inputs as shown in FIG. 4. The control signal phi1 may control the charging process of the bootstrap capacitor 401. The control signal phi1 may be set to a reference voltage level (i.e., set to a High status) during the first phase 511 of the operation process to turn on the charging control switch 402. The bootstrap capacitor 401 may be charged when the charging control switch 402, 403A, 403B, 403C are all turned on. During the first phase, the control signals phi1chA, phi1chB, and phi1chC, which control the switches 414A, 414B, and 414C, respectively, may be set to the reference voltage level (i.e., set to a High status) to turn on the switches 414A, 414B, and 414C. When the switches 414A, 414B, and 414C are turned on, the control signal inputs of the sampling switches for the three channels (e.g., 412A and 413A for channel A, 412B and 413B for channel B, 412C and 413C for channel C) may be grounded to zero. As a result, the sampling switches for three channels (e.g., 412A and 413A for channel A, 412B and 413B for channel B, 412C and 413C for channel C) may be turned off.

During the first sub-phase 521 of the second phase, the control signal phi1chA may be set to Low status. As a result, the switch 414A may be turned off. At the same time, the control signal phi2chA may be set to High status, which turns on the switch 411A connecting the bootstrap capacitor 401 to the control signal input of the sampling switches 412A and 413A for the channel A. As a result, the control signal input of the sampling switches 412A and 413A for the channel A may be set to the bootstrapped voltage of on the bootstrap capacitor 401 and the sampling switches 412A and 413A are bootstrapped and turned on to allow the input signal Vin to pass through them to reach the sampling capacitor 417A. During the first sub-phase 521 of the second phase, the control signals phi1chaB and phi1chC may be both set to High status and the control signals phi2chaB and phi2chaC may be set to Low status.

During the second sub-phase 522 of the second phase, the control signal phi1chB may be set to Low status. As a result, the switch 414B may be turned off. At the same time, the control signal phi2chB may be set to High status, which turns on the switch 411B connecting the bootstrap capacitor 401 to the control signal input of the sampling switches 412B and 413B for the channel B. As a result, the control signal input of the sampling switches 412B and 413B for the channel B may be set to the bootstrapped voltage of on the bootstrap capacitor 401 and the sampling switches 412B and 413B may be bootstrapped and turned on to allow the input signal Vin to pass through them to reach the sampling capacitor 417B. During the second sub-phase 522 of the second phase, the control signals phi1chaA and phi1chC may be both set to High status and the control signals phi2chaA and phi2chaC may be set to Low status.

During the third sub-phase 523 of the second phase, the control signal philchC may be set to Low status. As a result, the switch 414C may be turned off. At the same time, the control signal phi2chC may be set to High status, which turns on the switch 411C connecting the bootstrap capacitor 401 to the control signal input of the sampling switches 412C and 413C for the channel C. As a result, the control signal input of the sampling switches 412C and 413C for the channel C may be set to the bootstrapped voltage of on the bootstrap capacitor 401 and the sampling switches 412C and 413C may be bootstrapped and turned on to allow the input signal Vin to pass through them to reach the sampling capacitor 417C. During the third sub-phase 523 of the second phase, the control signals phi1chaA and phi1chB may be both set to High status and the control signals phi2chaA and phi2chaB may be set to Low status.

FIG. 6 illustrates an example electrical circuit 600 having a separate input signal for each channel and multiple sampling switches sharing a single bootstrapping capacitor in a time multiplexing manner. In particular embodiments, for signal sampling application, cach channel of the electrical circuit may be connected to a separate input signal (rather than being connected to the same input signal as in the first example for signal filtering application). Such circuit may function as an analog sampling circuit, allowing different input signals (which can be from different sensors) to be temporally held by the output sampling capacitors of respective channels to be later processed sequentially by a single A/D converter. As an example and not by way of limitation, FIG. 6 shows an example electrical circuit 600 which has a separate input signal for cach channel (e.g., the input signal VinchA for the channel A, VinchaB for the channel B, VinchaC for the channel C). These input signals may be from different signal sources (e.g., sensors). The electrical circuit 600 may be controlled by the control signals as shown in FIG. 5 to operate in a two-phase operation process. In the first phase, the bootstrap capacitor 401 may be charged to a reference voltage level. In the second phase, the sampling switches of each channel may be turned on sequentially during different sub-phases to allow the input signal VinchA to be sampled by the sampling capacitor 417A during a first time window, the input signal VinchB to be sampled by the sampling capacitor 417B during a second time window, and the input signal VinchC to be sampled by the sampling capacitor 417C during a third time window. After all input signals have been sampled by respective capacitors, these capacitors may cach hold a value that can be processed by a later circuit (e.g., a single ADC) sequentially in time.

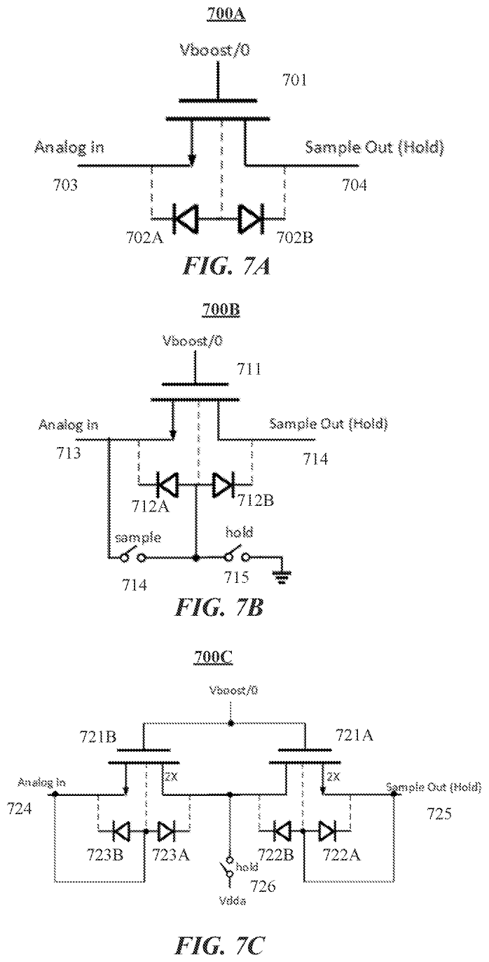

FIGS. 7A-7C illustrate example implementations 700A, 700B, and 700C of the sampling switches with multiple transistor switches arranged in series. In particular embodiments, the gate-to-bulk voltage may be higher than a limit if the bulk is tied to ground. In particular embodiments, the bulk may be locally connected to source to prevent this. However, this may face technical difficult if the analog input can be higher than the sampling output. For example, in sensor applications, inputs may be known or may change fast. To solve this problem, in particular embodiments, the electrical circuit may include sampling switches that are implemented as shown in FIGS. 7A-7C. In FIG. 7A, the implementation 700A may include two diodes 702A and 702B arranged in a reversed series order, connecting the analog input end 703 and the sample output end 704. The control signal input 701 may be bootstrapped. In FIG. 7B, the implementation 700B may include two diodes 712A and 712B arranged in a reversed series order, connecting the analog input end 713 and the sample output end 714. The control signal input 711 may be bootstrapped. The analog input end 713 may be connected to the middle point of the two diodes 712A and 712B by a sampling switch 714, which is further connected to ground by a hold switch 715. In FIG. 7C, the implementation 700C may include two sub-circuits each corresponding to a circuit as shown in FIG. 7A. The switches 721A and 721B may be connected in a reversed series order. The middle point of the two switches 721A and 721B may be connected to the supply voltage Vdd through a hold switch 726. In particular embodiments, the electrical circuit may prevent large Gate to bulk voltages during sampling processes. When Vgate=Vdd+Vin and the bulk is at the zero voltage, the Gate to bulk voltage Vgate may be a very large voltage, which may negatively impact the safety and reliability of the device. In particular embodiments, the electrical circuit may have the bulk connected to the source. In particular embodiments, the output sampling values may be larger than input values which causes the diode to be turned ON. In particular embodiments, the electrical circuit may be implemented using a more robust solution where two back-to-back NMOS transistors are used with their bulk and source being connected. The middle node may be connected to the voltage supply Vdd when the sampling switch is in OFF model (i.e., Vgate=0V) to ensure the diode is reversely biased. When the sampling switch is in the sampling mode, the voltage Vgatc =Vdd+Vin may be connected to the middle node of both sampling switches to turn on the diode.

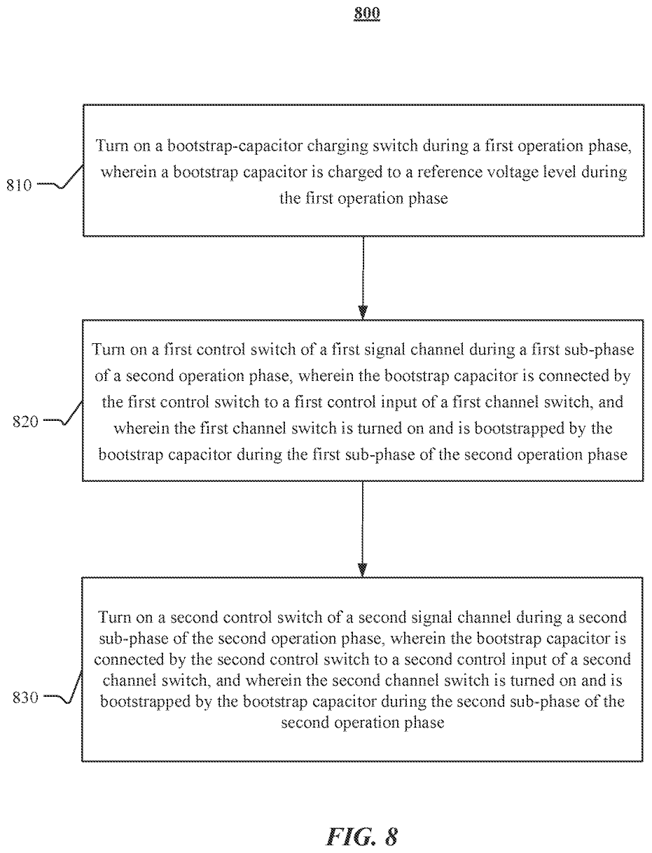

FIG. 8 illustrates an example method 800 of bootstrapping multiple switches using a single bootstrapping capacitor. The method may begin at step 810, where an electrical device may turn on a bootstrap-capacitor charging switch during a first operation phase, wherein a bootstrap capacitor is charged to a reference voltage level during the first operation phase. At step 820, the electrical device may turn on a first control switch of a first signal channel during a first sub-phase of a second operation phase, wherein the bootstrap capacitor is connected by the first control switch to a first control input of a first sampling switch, and wherein the first sampling switch is turned on and is bootstrapped by the bootstrap capacitor during the first sub-phase of the second operation phase. At step 830, the electrical device may turn on a second control switch of a second signal channel during a second sub-phase of the second operation phase, wherein the bootstrap capacitor is connected by the second control switch to a second control input of a second sampling switch, and wherein the second sampling switch is turned on and is bootstrapped by the bootstrap capacitor during the second sub-phase of the second operation phase.

In particular embodiments, an electrical circuit module may comprise a bootstrap capacitor connected to a bootstrap-capacitor charging switch that controls a charging process of the bootstrap capacitor. The electrical circuit module may comprise a first signal channel comprising a first sampling switch and a first control switch that controls a first connection between the bootstrap capacitor and a first control input of the first sampling switch. The electrical circuit module may comprise a second signal channel comprising a second sampling switch and a second control switch that controls a second connection between the bootstrap capacitor and a second control input of the second sampling switch. The bootstrap capacitor may be charged during a first operation phase during which the bootstrap-capacitor charging switch is turned on to allow the bootstrap capacitor to be charged. The first control switch of the first signal channel may be turned on during a first sub-phase of a second operation phase to allow the bootstrap capacitor to be connected to the first control input of the first sampling switch and allow the first sampling switch to be turn on and to be bootstrapped by the bootstrap capacitor. The second control switch of the second signal channel may be turned on during a second sub-phase of the second operation phase to allow the bootstrap capacitor to be connected to the second control input of the second sampling switch and allow the second sampling switch to be turned on and to be bootstrapped by the bootstrap capacitor.

In particular embodiments, the first control switch of the first channel and the second control switch of the second channel may be turned off during the first operation phase, and wherein the bootstrap capacitor may be electrically disconnected from the first control input of the first sampling switch of the first signal channel and the second control input of the second sampling switch of the second signal channel. In particular embodiments, the second control switch of the second signal channel may be turned off during the first sub-phase of the second operation phase. In particular embodiments, the first control switch of the first signal channel may be turned off during the second sub-phase of the second operation phase. In particular embodiments, the bootstrap-capacitor charging switch may be turned off during the second operation phase. In particular embodiments, the electrical circuit module may further comprise a first sampling capacitor for the first signal channel, the first sampling capacitor being connected to a first output end of the first sampling switch of the first signal channel, and a second sampling capacitor for the second signal channel, the second sampling capacitor being connected to a second output end of the second sampling switch of the second signal channel.

In particular embodiments, the first sampling capacitor may hold a first voltage value of the first output end of the first sampling switch of the first signal channel, and wherein the second sampling capacitor may hold a second voltage value of the second output end of the second sampling switch of the second signal channel. In particular embodiments, the bootstrap capacitor charging switch may comprise at least: a first transistor switch that is controlled by a first control signal from the first control input of the first sampling switch of the first signal channel, and a second transistor switch that is controlled by a second control signal from the second control input of the second sampling switch of the second signal channel.

In particular embodiments, the bootstrap capacitor charging switch may turned on when at least the first sampling switch is turned off by the first control signal and the second channel is turned off by the second control signal. In particular embodiments, the electrical circuit module may further comprise a first control-signal switch that controls the first control signal on the first control signal input of the first sampling switch, where the first control-signal switch is turned on during the first operation phase during which the bootstrap capacitor is charged, and the first control signal input of the first sampling switch is grounded to turn off the first sampling switch. The electrical circuit module may comprise a second control signal switch that controls the second control signal on the second control signal input of the second sampling switch, wherein the second control-signal switch is turned on during the first operation phase during which the bootstrap capacitor is charged, and the second control signal input of the second sampling switch is grounded to turn off the second sampling switch. In particular embodiments, the first control-signal switch may be turned off during the first sub-phase of the second operation phase, and wherein the first control signal input of the first sampling switch of the first channel may be pulled to a reference voltage to turn on the first sampling switch of the first channel.

In particular embodiments, the second control-signal switch of the second signal channel may be turned on and the second control signal input of the second sampling switch of the second channel may be grounded to turn off the second sampling switch. In particular embodiments, the second control-signal switch may be turned off during the second sub-phase of the second operation phase, and wherein the second control signal input of the second sampling switch of the second channel may be pulled to a reference voltage to turn on the second sampling switch of the second channel. In particular embodiments, the first control-signal switch of the first signal channel may be turned on and the first control signal input of the first sampling switch of the first channel is grounded to turn off the first sampling switch. In particular embodiments, the first sampling switch may comprise a first transistor switch and a second transistor switch, and wherein the first transistor switch and the second transistor switch may share a same control signal from a same control signal input. In particular embodiments, the electrical circuit module may further comprise a plurality of signal channels, wherein each of the plurality of signal channels may comprise an associated sampling switch, and wherein the plurality of associated sampling switches of the plurality of signal channels, the first sampling switch of the first channel, the second sampling switch of the second channel may share the bootstrap capacitor in a time multiplexing manner. In particular embodiments, the bootstrap capacitor may have a capacitance value depending on a number of sampling switches that share the bootstrap capacitor. In particular embodiments, a first signal input of the first sampling switch of the first channel and a second signal input of the second sampling switch of the second channel may be connected to a same input signal. In particular embodiments, a first signal input of the first sampling switch of the first channel may be connected to a first input signal, and wherein a second signal input of the second sampling switch of the second channel may be connected to a second input signal.

Particular embodiments may repeat one or more steps of the method of FIG. 8, where appropriate. Although this disclosure describes and illustrates particular steps of the method of FIG. 8 as occurring in a particular order, this disclosure contemplates any suitable steps of the method of FIG. 8 occurring in any suitable order. Moreover, although this disclosure describes and illustrates an example method of bootstrapping multiple switches using a single bootstrapping capacitor including the particular steps of the method of FIG. 8, this disclosure contemplates any suitable method of bootstrapping multiple switches using a single bootstrapping capacitor including any suitable steps, which may include all, some, or none of the steps of the method of FIG. 8, where appropriate. Furthermore, although this disclosure describes and illustrates particular components, devices, or systems carrying out particular steps of the method of FIG. 8, this disclosure contemplates any suitable combinations of any suitable components, devices, or systems carrying out any suitable steps of the method of FIG. 8.

What is claimed is:

1. An electrical circuit module, comprising:
a bootstrap capacitor connected to a bootstrap-capacitor charging switch that controls a charging process of the bootstrap capacitor;
a first signal channel comprising a first sampling switch and a first control switch that controls a first connection between the bootstrap capacitor and a first control input of the first sampling switch; and
a second signal channel comprising a second sampling switch and a second control switch that controls a second connection between the bootstrap capacitor and a second control input of the second sampling switch, wherein:
the bootstrap capacitor is charged during a first operation phase during which the bootstrap-capacitor charging switch is turned on to allow the bootstrap capacitor to be charged;
the first control switch of the first signal channel is turned on during a first sub-phase of a second operation phase to allow the bootstrap capacitor to be connected to the first control input of the first sampling switch and allow the first sampling switch to be turn on and to be bootstrapped by the bootstrap capacitor; and
the second control switch of the second signal channel is turned on during a second sub-phase of the second operation phase to allow the bootstrap capacitor to be connected to the second control input of the second sampling switch and allow the second sampling switch to be turned on and to be bootstrapped by the bootstrap capacitor.

2. The electrical circuit module of claim 1, wherein the first control switch of the first channel and the second control switch of the second channel are turned off during the first operation phase, and wherein the bootstrap capacitor is electrically disconnected from the first control input of the first sampling switch of the first signal channel and the second control input of the second sampling switch of the second signal channel.

3. The electrical circuit module of claim 1, wherein the second control switch of the second signal channel is turned off during the first sub-phase of the second operation phase.

4. The electrical circuit module of claim 1, wherein the first control switch of the first signal channel is turned off during the second sub-phase of the second operation phase.

5. The electrical circuit module of claim 1, wherein the bootstrap-capacitor charging switch is turned off during the second operation phase.

6. The electrical circuit module of claim 1, further comprising:
a first sampling capacitor for the first signal channel, the first sampling capacitor being connected to a first output end of the first sampling switch of the first signal channel; and
a second sampling capacitor for the second signal channel, the second sampling capacitor being connected to a second output end of the second sampling switch of the second signal channel.

7. The electrical circuit module of claim 6, wherein the first sampling capacitor holds a first voltage value of the first output end of the first sampling switch of the first signal channel, and wherein the second sampling capacitor holds a second voltage value of the second output end of the second sampling switch of the second signal channel.

8. The electrical circuit module of claim 6, wherein the bootstrap capacitor charging switch comprises at least:
a first transistor switch that is controlled by a first control signal from the first control input of the first sampling switch of the first signal channel; and
a second transistor switch that is controlled by a second control signal from the second control input of the second sampling switch of the second signal channel.

9. The electrical circuit module of claim 8, wherein the bootstrap capacitor charging switch is turned on when at least the first sampling switch is turned off by the first control signal and the second channel is turned off by the second control signal.

10. The electrical circuit module of claim 9, further comprising:
a first control-signal switch that controls the first control signal on the first control signal input of the first sampling switch, where the first control-signal switch is turned on during the first operation phase during which the bootstrap capacitor is charged, and the first control signal input of the first sampling switch is grounded to turn off the first sampling switch; and
a second control-signal switch that controls the second control signal on the second control signal input of the second sampling switch, wherein the second control-signal switch is turned on during the first operation phase during which the bootstrap capacitor is charged, and the second control signal input of the second sampling switch is grounded to turn off the second sampling switch.

11. The electrical circuit module of claim 10, wherein the first control-signal switch is turned off during the first sub-phase of the second operation phase, and wherein the first control signal input of the first sampling switch of the first channel is pulled to a reference voltage to turn on the first sampling switch of the first channel.

12. The electrical circuit module of claim 11, wherein the second control-signal switch of the second signal channel is turned on and the second control signal input of the second sampling switch of the second channel is grounded to turn off the second sampling switch.

13. The electrical circuit module of claim 10, wherein the second control-signal switch is turned off during the second sub-phase of the second operation phase, and wherein the second control signal input of the second sampling switch of the second channel is pulled to a reference voltage to turn on the second sampling switch of the second channel.

14. The electrical circuit module of claim 13, wherein a first time duration of the first sub-phase is based on a first sampling speed of the first signal channel, and wherein a second time duration of the second sub-phase is based on a second sampling speed of the second signal channel.

15. The electrical circuit module of claim 1, wherein the first sampling switch comprises a first transistor switch and a second transistor switch, and wherein the first transistor switch and the second transistor switch share a same control signal from a same control signal input.

16. The electrical circuit module of claim 1, further comprising a plurality of signal channels, wherein each of the plurality of signal channels comprises an associated sampling switch, and wherein the plurality of associated sampling switches of the plurality of signal channels, the first sampling switch of the first channel, the second sampling switch of the second channel share the bootstrap capacitor in a time multiplexing manner.

17. The electrical circuit module of claim 16, wherein the bootstrap capacitor has a capacitance value depending on a number of sampling switches that share the bootstrap capacitor.

18. The electrical circuit module of claim 1, wherein a first signal input of the first sampling switch of the first channel and a second signal input of the second sampling switch of the second channel are connected to a same input signal.

19. The electrical circuit module of claim 1, wherein a first signal input of the first sampling switch of the first channel is connected to a first input signal, and wherein a second signal input of the second sampling switch of the second channel is connected to a second input signal.

20. A method of bootstrapping multiple sampling switches using a single bootstrapping capacitor comprising, by an electrical device:
turning on a bootstrap-capacitor charging switch during a first operation phase, wherein a bootstrap capacitor is charged to a reference voltage level during the first operation phase;
turning on a first control switch of a first signal channel during a first sub-phase of a second operation phase, wherein the bootstrap capacitor is connected by the first control switch to a first control input of a first sampling switch, and wherein the first sampling switch is turned on and is bootstrapped by the bootstrap capacitor during the first sub-phase of the second operation phase; and
turning on a second control switch of a second signal channel during a second sub-phase of the second operation phase, wherein the bootstrap capacitor is connected by the second control switch to a second control input of a second sampling switch, and wherein the second sampling switch is turned on and is bootstrapped by the bootstrap capacitor during the second sub-phase of the second operation phase.
